(19) United States
(12) Patent Application Publication
(10) Pub. No.: US 2015/0155176 A1
(43) Pub. Date: Jun. 4, 2015

(54) SIDEWALL HEIGHT NONUNIFORMITY REDUCTION FOR SIDEWALL IMAGE TRANSFER PROCESSES

(71) Applicants: STMicroelectronics, Inc., Coppell, TX (US); Lam Research Corporation, Fremont, CA (US)

(72) Inventors: Yann MIGNOT, Slingerlands, NY (US); Bhaskar NAGABHIRAVA, Albany, NY (US)

(73) Assignees: Lam Research Corporation, Fremont, CA (US); STMicroelectronics, Inc., Coppell, TX (US)

(21) Appl. No.: 14/094,858

(22) Filed: Dec. 3, 2013

(51) Int. Cl. H01L 21/3065; H01L 27/04; H01L 21/308

(52) U.S. Cl. CPC H01L 21/3065; H01L 21/3081; H01L 21/3086; H01L 27/04

(57) ABSTRACT

A method and integrated circuit structure. The method includes reducing sidewall height nonuniformity in sidewall image transfer processes by depositing an organic planarization layer over the integrated circuit structure after sidewall definition, mandrel removal, and etch of exposed portions of a first underlying layer in a sidewall image transfer process that is thick enough to cover one or more first sidewalls having a first height and one or more second sidewalls having a second height with the first height greater than the second height, removing a part of the organic planarization layer leaving a first depth of the one or more first sidewalls exposed, removing the exposed first depth of the one or more first sidewalls, and removing the remaining organic planarization layer.

### TECHNICAL FIELD

The present disclosure relates to the fabrication of integrated circuits, and in particular, to sidewall image transfer processes.

### BACKGROUND

In the semiconductor industry there is a continuing trend toward manufacturing integrated circuits (ICs) with higher densities. Smaller feature sizes, smaller separations between features and more precise feature shapes are desired in integrated circuits (ICs) fabricated on small rectangular portions of the wafer, commonly known as dies. This may include the width and spacing of interconnecting lines, spacing and diameter of contact holes, as well as the surface geometry of various other features (e.g., corners and edges). The scaling-down of integrated circuit dimensions can facilitate faster circuit performance and/or switching speeds, and can lead to higher cost efficiency in IC fabrication by providing more circuits on a die and/or more die per semiconductor wafer. The minimum planar dimension of a feature that can be reliably created in an integrated circuit (IC) process is referred to as its critical dimension. Often the critical dimension for a given IC process is limited by the resolution of its photolithographic processes.

### BRIEF DESCRIPTION OF THE DRAWINGS

Example embodiments of the present disclosure will be described below with reference to the included drawings such that like reference numerals refer to like elements and in which:

FIG. 1 illustrates a side view of an integrated circuit structure fabricated using a sidewall image transfer process following sidewall definition, mandrel removal, and subsequent etch of the exposed portions of the first underlying layer in accordance with embodiments of the present disclosure;

FIG. 2 illustrates a side view of the integrated circuit structure of FIG. 1 following deposition of an organic planarization layer in accordance with embodiments of the present disclosure;

FIG. 3 illustrates a side view of the integrated circuit structure of FIG. 2 following a partial removal of the organic planarization layer in accordance with embodiments of the present disclosure;

FIG. 4 illustrates a side view of the integrated circuit structure of FIG. 3 following an etch of the exposed first depth of the first sidewalls in accordance with embodiments of the present disclosure;

FIG. 5 illustrates a side view of the integrated circuit structure of FIG. 4 following removal of the remaining organic planarization layer in accordance with embodiments of the present disclosure;

FIG. 6 illustrates a side view of the integrated circuit structure of FIG. 2 following an alternative partial removal of the organic planarization layer in accordance with embodiments of the present disclosure;

FIG. 7 illustrates a side view of the integrated circuit structure of FIG. 6 following an etch of the exposed first depth of the first sidewalls and of the exposed second depth of the second sidewalls in accordance with embodiments of the present disclosure;

FIG. 8 illustrates a side view of the integrated circuit structure of FIG. 7 following removal of the remaining organic planarization layer in accordance with embodiments of the present disclosure; and

FIG. 9 illustrates a flow chart of a method for reducing sidewall height variation in a sidewall image transfer process in accordance with embodiments of the present disclosure.

### DETAILED DESCRIPTION

For simplicity and clarity of illustration, reference numerals may be repeated among the figures to indicate corresponding or analogous elements. The sizes and relative positions of elements in the drawings are not necessarily drawn to scale. Numerous details are set forth to provide an understanding of the illustrative embodiments described herein. The embodiments may be practiced without these details. In other instances, well-known methods, procedures, and components have not been described in detail to avoid obscuring the disclosed embodiments. The description is not to be considered as limited to the scope of the exemplary embodiments shown and described herein.

The terms “a” or “an”, as used herein, are defined as one or more than one. The term “plurality”, as used herein, is defined as two or more than two. The term “another”, as used herein, is defined as at least a second or more. The terms “including” and/or “having”, as used herein, are defined as comprising (i.e., open language). The term “coupled”, as used herein, is defined as connected, although not necessarily directly, and not necessarily mechanically. The term “or” as used herein is to be interpreted as an inclusive or meaning any one or any combination. Therefore, “A, B or C” means “any of the following: A; B; C; A and B; A and C; B and C; A, B and C”. An exception to this definition will occur only when a combination of elements, functions, steps or acts are in some way inherently mutually exclusive.

Reference throughout this document to “one embodiment”, “certain embodiments”, “an embodiment”, “an example”, “an implementation”, “an example” or similar terms means that a particular feature, structure, or characteristic described in connection with the embodiment, example or implementation is included in at least one embodiment, example or implementation of the present invention. Thus, the appearances of such phrases or in various places throughout this specification are not necessarily all referring to the same embodiment, example or implementation. Furthermore, the particular features, structures, or characteristics may be combined in any suitable manner in one or more embodiments, examples or implementations without limitation.

Unless the context requires otherwise, throughout the specification and claims that follow, the word “comprise” and variations thereof, such as “comprises” and “comprising” are to be construed in an open, inclusive sense, that is, as “including, but not limited to.”

As shown in the drawings for purposes of illustration, novel techniques are disclosed herein for the reduction in nonuniformity of sidewall heights for sidewall image transfer processes. As used herein the terms “sidewall” and “spacer” are interchangeable in meaning and in reference to elements.

A technique used to circumvent the limitations of current photolithographic processes is spacer lithography. Processes that use spacer lithography are referred to as spacer image transfer processes or sidewall image transfer processes. Following the patterning of a sacrificial layer in such processes, a layer of hard masking material is conformally deposited and then anisotropically etched. This processing ideally results in leaving only a vertical layer of the hard masking material on the sidewalls of the patterned sacrificial layer. The sacrificial layer is then removed, certain areas of the hard masking material are removed, and subsequently the pattern defined by the vertical layers of hard masking material are etched into an underlying layer. The result is a critical dimension which is less than the critical dimension of the photolithographic process alone and which is now dependent upon the thickness of the conformal layer

A blocking photolithographic mask is used in sidewall image transfer processes following sidewall creation to block off areas of the circuitry from subsequent etching of the sidewall defined openings into a lower hard layer. Following this hard mask etch process there will be two different heights of sidewalls (spacers) with the greater sidewall (spacer) height occurring in areas in which the etching was blocked. Sidewall image transfer processes are often referred to as spacer image transfer processes or by use of the acronym SIT.

Differences created in sidewall heights result in two potential subsequent processing problems. First the difference in heights of the topography can create photolithography exposure interferences. Second, sidewall residues due to incomplete sidewall removal in some areas can result in delamination during subsequent processing.

Techniques are disclosed herein which alleviate these problems. After opening the hard mask and subsequent removal of the blocking photolithographic mask, an organic planarization layer (OPL) is laid down over the circuitry covering both the taller and the shorter sidewalls. The OPL layer is etched back partially exposing an upper part of the taller sidewalls with the shorter sidewalls remaining either covered or partially covered by the remaining OPL. This upper exposed part of the taller sidewalls is then removed thereby reducing the height of the taller sidewalls. If the shorter sidewalls are only partially covered, the exposed part of the shorter sidewalls is also removed thereby reducing the height of the shorter sidewalls. Finally, the remaining OPL is removed. This process, as disclosed herein in representative embodiments, results in smaller differences between the taller and the shorter sidewalls.

While the present invention is subject to embodiment in many different forms, there is shown in the drawings and will herein be described in detail one or more specific embodiments, with the understanding that the present disclosure is to be considered as exemplary of the principles of the invention and not intended to limit the invention to the specific embodiments shown and described. In the following description and in the several figures of the drawings, like reference numerals are used to describe the same, similar or corresponding parts in the several views of the drawings.

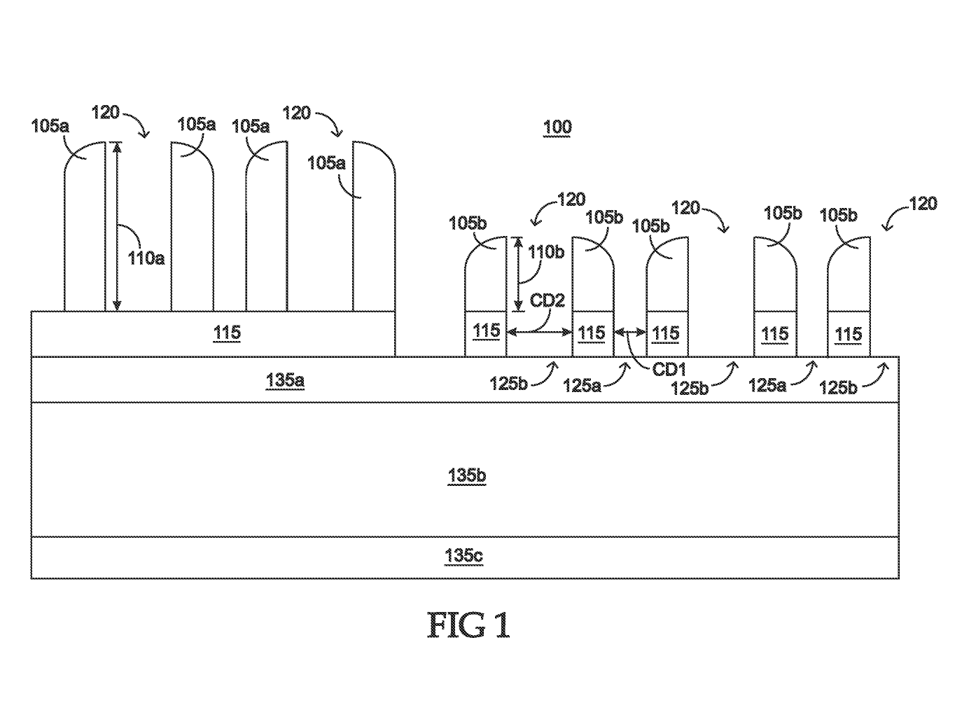

FIG. 1 illustrates a side view of an integrated circuit structure 100 fabricated using a sidewall image transfer process following sidewall 105 definition, mandrel removal, and subsequent etch of the exposed portions of the first underlying layer 115 in accordance with embodiments of the present disclosure. Representative additional underlying layers 135a,135b,135c are also shown for illustrative purposes only in the various figures. For ease and clarity of illustration, the sidewalls 105 and other elements in the figures are shown as idealized geometries.

In FIG. 1, the sidewalls 105 comprise first sidewalls 105a and second sidewalls 105b with the first sidewalls 105a extending from a first underlying layer 115 a first height 110a and the second sidewalls 105b extending from the first underlying layer 115 a second height 110b. The first openings 125a and second openings 125b are referred to collectively as the openings 125.

The first sidewalls 105a and second sidewalls 105b referred to herein generally as the sidewalls 105 were created using a sidewall image transfer process. Also shown in FIG. 1 are locations 120 where mandrels were previously located. The mandrels which are not shown in any of the figures were the pattered remains of a sacrificial layer laid down over the first underlying layer 115 and used in defining the sidewalls 105. In a representative embodiment the first underlying layer 115 can be, for example, 25 nanometers.

In the sidewall image transfer process the sacrificial layer is laid down and patterned leaving the mandrels. Then a layer of hard masking material is conformally deposited and anisotropically etched ideally leaving only a vertical layer, i.e., the sidewalls 105 of the hard masking material on the sidewalls of the patterned sacrificial layer. The mandrels are then removed. Subsequently the pattern defined by the vertical layers of hard masking material are etched into the first underlying layer 115 with, however, selected areas of the circuitry blocked from this etching process with resultant difference between the heights of the first and the second sidewalls 105a,105b. The result of these processing steps is a first critical dimension CD1 created within the first opening 125a which lies between two sidewalls formed on adjacent sides of two adjacent mandrels, and a second critical dimension CD2 created within the second opening 125b which was previously occupied by a mandrel. The first critical dimension CD1 which is dependent upon the thickness of the conformal layer is less than the second critical dimension CD2 which is defined by the photolithographic process alone. For purposes of illustration clarity, only one of the first critical dimensions CD1 and one of the second critical dimensions CD2 are identified as such in the figures.

In representative embodiments, the first critical dimension CD1 can have, for example, a nominal value of approximately 22 nanometers, and the second critical dimension CD2 can have, for example, a nominal value of approximately 28 nanometers. Also, in representative embodiments the first height 110a can be, for example, nominally 80 nanometers and the second height 110b can be, for example, nominally 30 nanometers.

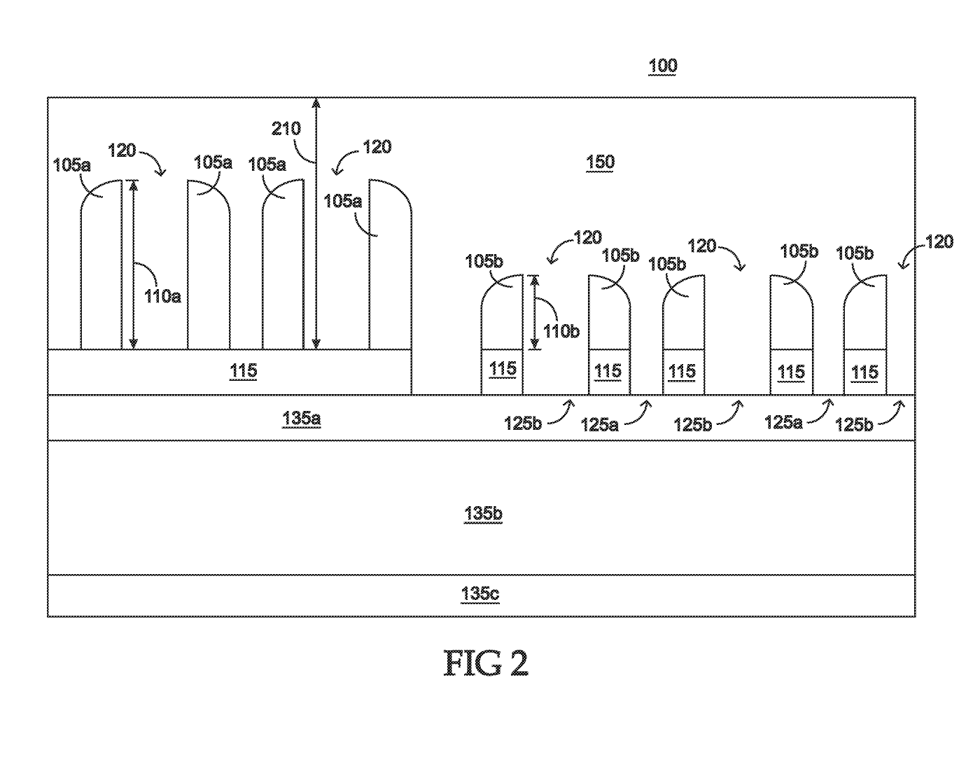

FIG. 2 illustrates a side view of the integrated circuit structure 100 of FIG. 1 following deposition of an organic planarization layer 150 in accordance with embodiments of the present disclosure. Organic planarization layers 150 are often referred to using the acronym OPL in place of organic planarization layer. In FIG. 2, an organic planarization layer 150 has been laid down a planarization layer thickness 210 thick enough to cover both the first and the second sidewalls 105a,105b. In a representative embodiment the first height 110a can be, for example, nominally one-and-a-half as thick as the first height 110a, the material of the organic planarization layer 150 could be, but not limited to, ODL-102 or ODL-401 which is commercially available from Shin-Etsu Chemical Co., Ltd. or JSRHM8833 which is commercially available from JSR Corporation. The material of the organic planarization layer 150 could also be, but not limited to, a hydrocarbon component of greater than approximately 75% and less than approximately 90% by weight with the remaining components comprising a combination of oxygen with hydrogen, and nitrogen of greater than approximately 5% and less than approximately 20% by weight. The organic planarization layer 150 could be laid down, for example, by spinning onto the integrated circuit structure 100.

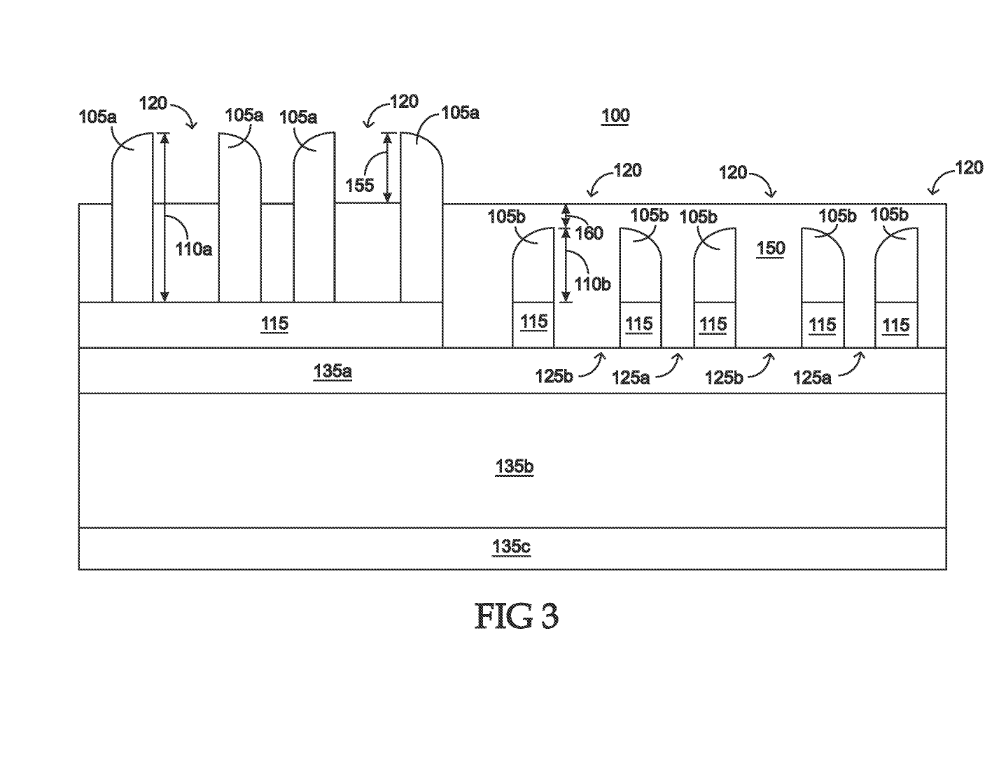

FIG. 3 illustrates a side view of the integrated circuit structure 100 of FIG. 2 following a partial removal of the organic planarization layer 150 in accordance with embodiments of the present disclosure. Prior to the view of FIG. 3, a part of the organic planarization layer 150 is removed using, for example, either oxygen (O₂), a nitrogen (N₂)/hydrogen (N₂) mixture, or a carbon monoxide (CO)/carbon dioxide (CO₂) mixture in a reactive ion plasma etch process which techniques are well known by those of ordinary skill in the art. The etching process is continued until a first depth 155 of the first sidewalls 105a is exposed but is terminated prior to exposing the second sidewalls 105b by a second depth 160. In a representative embodiment, the first depth 155 could be, for example, nominally 30 to 40 nanometers, and the second depth 160 preferably could be, for example, nominally 10 or more nanometers.

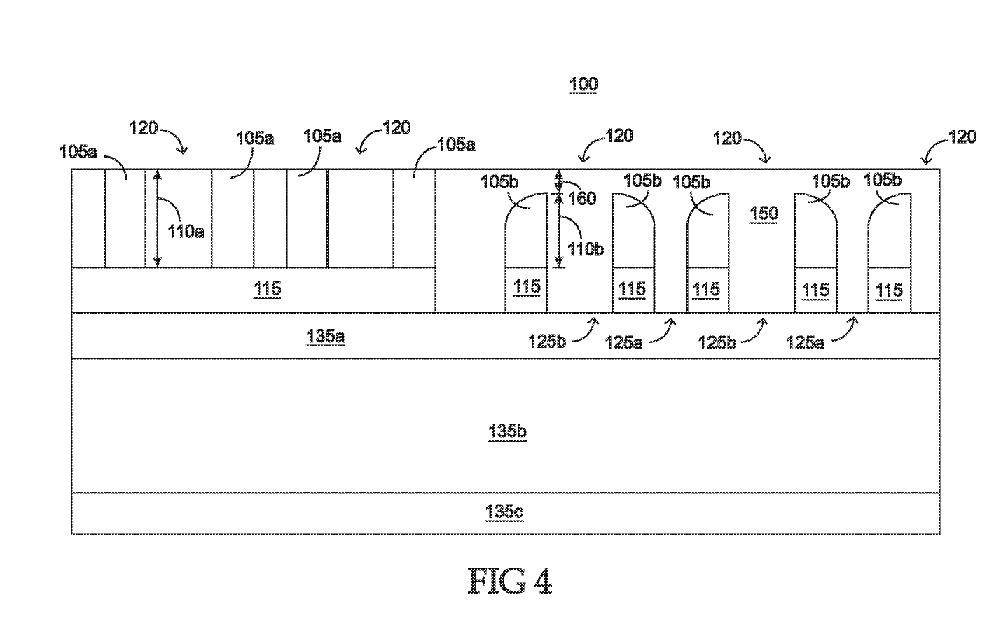

FIG. 4 illustrates a side view of the integrated circuit structure 100 of FIG. 3 following an etch of the exposed first depth 155 of the first sidewalls 105a in accordance with embodiments of the present disclosure. Prior to the view of FIG. 4, the exposed first depth 155 of the first sidewalls 105a is removed using, for example, a mixture of methane (CF₄), fluoroform (CHF₃), and fluoromethane (CH₃F) in a reactive ion plasma etch process which techniques are well known by those of ordinary skill in the art. The etching time could be fixed or alternatively variable if a plasma intensity monitor is used. Plasma intensity monitoring is also referred to as End Point monitoring. This technique monitors the wavelengths of the emitted light created in the reaction chamber as the plasma etches which provides an indication of the material remaining on the wafer. Process parameters for this etch are chosen so as to reduce etching of the organic planarization layer 150 while removing the exposed portions of the first sidewalls 105a.

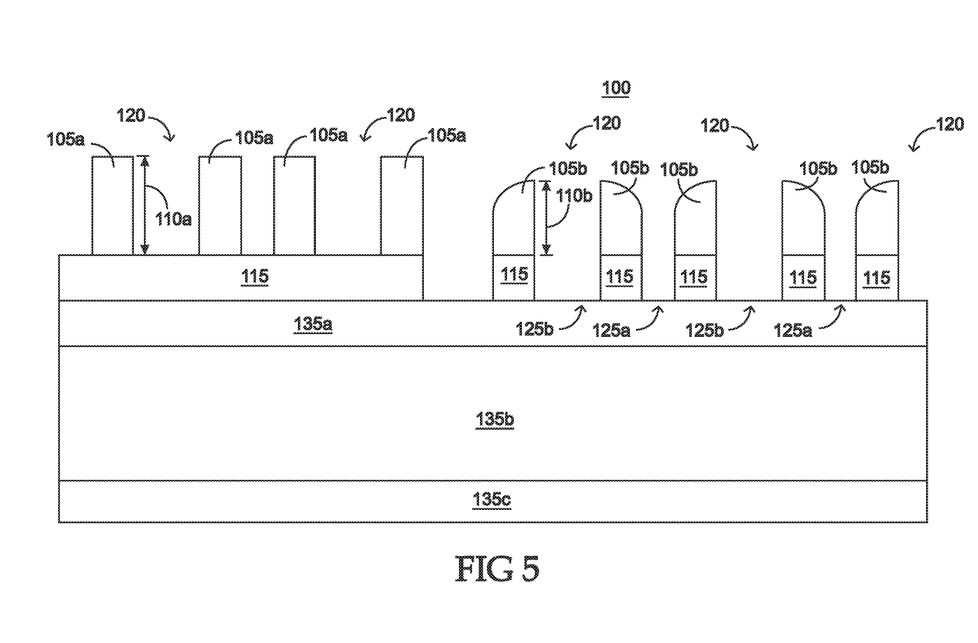

FIG. 5 illustrates a side view of the integrated circuit structure 100 of FIG. 4 following removal of the remaining organic planarization layer 150 in accordance with embodiments of the present disclosure. Prior to the view of FIG. 5, the remaining organic planarization layer 150 is removed using, for example, either oxygen (O₂), a nitrogen (N₂)/hydrogen (N₂) mixture, or a carbon monoxide (CO)/carbon dioxide (CO₂) mixture in a reactive ion plasma etch process which techniques are well known by those of ordinary skill in the art. The etching process was continued until the remaining organic planarization layer 150 was removed. Note that the remaining first height 110a of the first sidewall 105a now differs from the remaining second height 110b of the second sidewall 105b by less than it did prior to the processing indicated in FIG. 2 to FIG. 5.

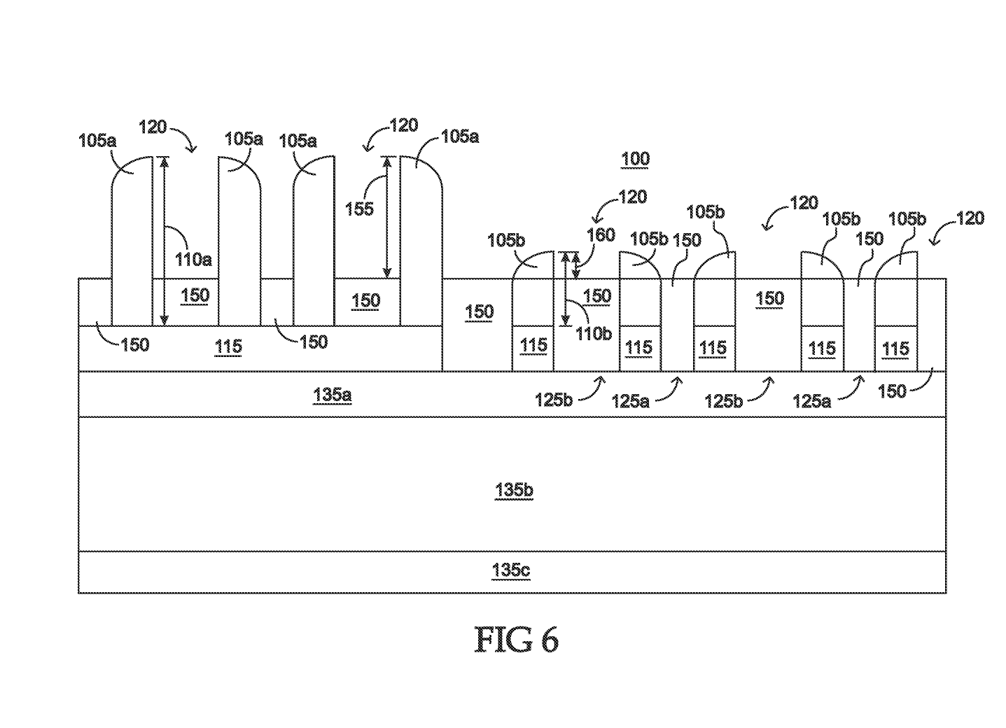

FIG. 6 illustrates a side view of the integrated circuit structure 100 of FIG. 2 following an alternative partial removal of the organic planarization layer 150 in accordance with embodiments of the present disclosure. Prior to the view of FIG. 6, a part of the organic planarization layer 150 is removed using, for example, either oxygen (O₂), a nitrogen (N₂)/hydrogen (N₂) mixture, or a carbon monoxide (CO)/carbon dioxide (CO₂) mixture in a reactive ion plasma etch process which techniques are well known by those of ordinary skill in the art. The etching process is continued until a first depth 155 of the first sidewalls 105a and a second depth 160 of second sidewalls 105b are exposed. In a representative embodiment, the first depth 155 could be, for example, nominally 40 to 50 nanometers, and the second depth 160 preferably could be, for example, nominally 10 or more nanometers below the top of the second sidewall 105b.

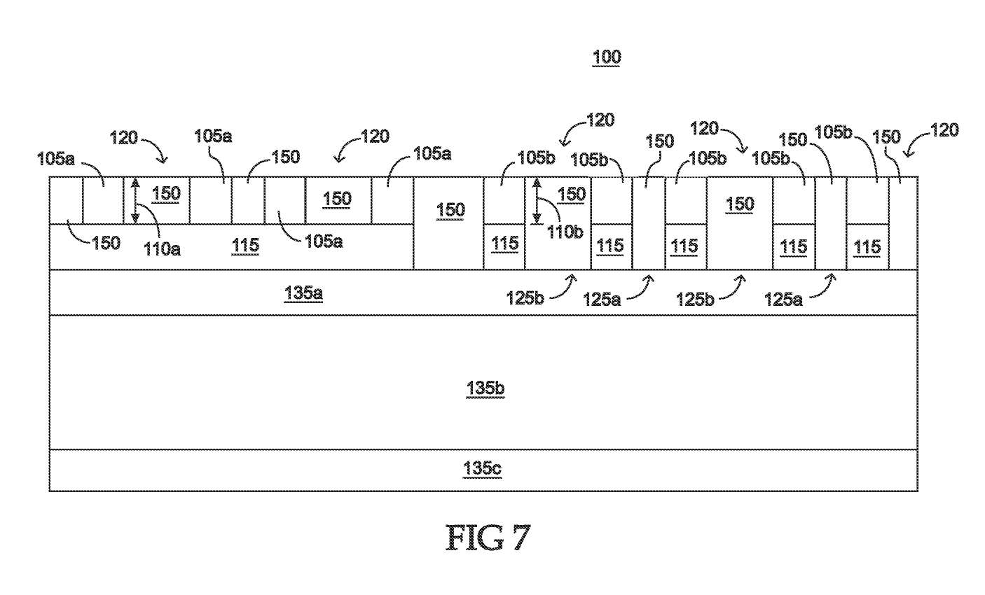

FIG. 7 illustrates a side view of the integrated circuit structure 100 of FIG. 6 following an etch of the exposed first depth 155 of the first sidewalls 105a and of the exposed second depth 160 of the second sidewalls 105b in accordance with embodiments of the present disclosure. Prior to the view of FIG. 7, the exposed first depth 155 of the first sidewalls 105a and of the exposed second depth 160 of the second sidewalls 105b shown in FIG. 6 is removed using, for example, a mixture of methane (CF₄), fluoroform (CHF₃), and fluoromethane (CH₃F) in a reactive ion plasma etch process which techniques are well known by those of ordinary skill in the art. The etching time could be fixed or alternatively variable if a plasma intensity monitor is used. Plasma intensity monitoring is also referred to as End Point monitoring. This technique monitors the wavelengths of the emitted light created in the reaction chamber as the plasma etches which provides an indication of the material remaining on the wafer. Process parameters for this etch are chosen so as to reduce etching of the organic planarization layer 150 while removing the exposed portions of the first sidewalls 105a.

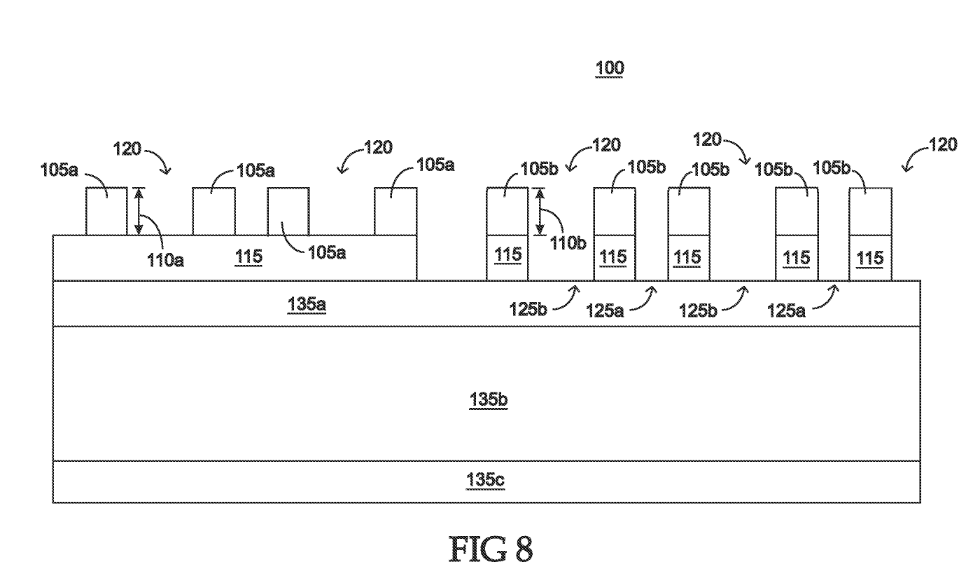

FIG. 8 illustrates a side view of the integrated circuit structure 100 of FIG. 7 following removal of the remaining organic planarization layer 150 in accordance with embodiments of the present disclosure. Prior to the view of FIG. 8, the remaining organic planarization layer 150 is removed using, for example, either oxygen (O₂), a nitrogen (N₂)/hydrogen (N₂) mixture, or a carbon monoxide (CO)/carbon dioxide (CO₂) mixture in a reactive ion plasma etch process which techniques are well known by those of ordinary skill in the art. The etching process is continued until the remaining organic planarization layer 150 was removed. Note that the remaining first height 110a of the first sidewall 105a now differs from the remaining second height 110b of the second sidewall 105b by less than it did prior to the processing indicated in FIG. 2 and in FIG. 6 to FIG. 8.

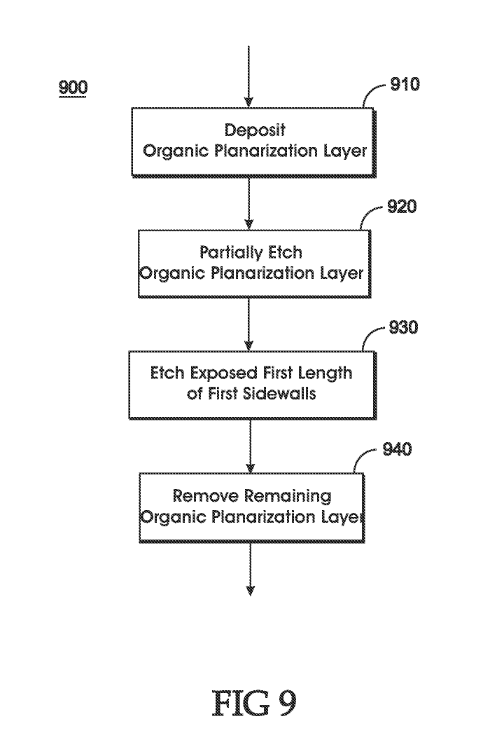

FIG. 9 illustrates a flow chart of a method 900 for reducing sidewall height variation in a sidewall image transfer process in accordance with embodiments of the present disclosure. In block 910 of FIG. 9, after sidewall 105 definition and subsequent hard mask etch in a sidewall image transfer process an organic planarization layer 150 is deposited over the circuitry. The organic planarization layer 150 is laid down thick enough to cover both the first and the second sidewalls 105a, 105b. Processing techniques, materials, and nominal values for representative implementations are disclosed above. Block 910 then transfers control to block 920.

In block 920, a partial removal of the organic planarization layer 150 is performed resulting in the exposure of a first depth 155 of the first sidewalls 105a and alternatively in the exposure of a second depth 160 of second sidewalls 105b. Processing techniques, materials, and nominal values for representative implementations are disclosed above. Block 920 then transfers control to block 930.

In block 930, the exposed first depth 155 of the first sidewalls 105a and alternatively the exposed second depth 160 of second sidewalls 105b are removed. Processing techniques, materials, and nominal values for representative implementations are disclosed above. Block 930 then transfers control to block 940.

In block 940, the remaining organic planarization layer 150 is removed. Processing techniques, materials, and nominal values for representative implementations are disclosed above. Block 940 then terminates the process.

In a representative embodiment, a method 900 for reducing sidewall height 110a,110b nonuniformity in sidewall image transfer processes is disclosed. The method 900 comprises depositing an organic planarization layer 150 over an integrated circuit structure 100 after sidewall 105 definition, mandrel removal, and etch of exposed portions of a first underlying layer 115 in a sidewall image transfer process, wherein the organic planarization layer 150 is laid down thick enough to cover both one or more first and one or more second sidewalls 105a,105b, wherein the one or more first sidewalls 105a have a first height 110a and the one or more second sidewalls 105b have a second height 110b, and wherein the first height 110a is greater than the second height 110b; removing a part of the organic planarization layer 150, wherein a first depth 155 of the one or more first sidewalls 105a is exposed and wherein the organic planarization layer 150 covers the one or more second sidewalls 105b by a second depth 160; removing the exposed first depth 155 of the one or more first sidewalls 105a; and removing the remaining organic planarization layer 150.

In another representative embodiment, another method 900 for reducing sidewall height 110a,110b nonuniformity in sidewall image transfer processes is disclosed. The method 900 comprises depositing an organic planarization layer 150 over an integrated circuit structure 100 after sidewall 105 definition, mandrel removal, and etch of exposed portions of a first underlying layer 115 in a sidewall image transfer process, wherein the organic planarization layer 150 is laid down thick enough to cover both one or more first and one or more second sidewalls 105a,105b, wherein the one or more first sidewalls 105a have a first height 110a and the one or more second sidewalls 105b have a second height 110b, and wherein the first height 110a is greater than the second height 110b; removing a part of the organic planarization layer 150, wherein a first depth 155 of the one or more first sidewalls 105a is exposed and wherein a second depth 160 of the one or more second sidewalls 160 is exposed; removing the exposed first depth 155 of the one or more first sidewalls 105a and the exposed second depth 160 of the one or more second sidewalls 105b; and removing the remaining organic planarization layer 150.

In still another representative embodiment, an integrated circuit structure 100 having reduced sidewall height 110a,110b nonuniformity in sidewall image transfer processes is disclosed. The integrated circuit structure 100 comprises one or more first sidewalls 105a having a first height 110a; and one or more second sidewalls 105b having a second height 110b, wherein after sidewall 105 definition, mandrel removal, and etch of exposed portions of a first underlying layer 115 the difference between the first height 110a and the second height 110b is reduced by depositing an organic planarization layer 150 over the integrated circuit structure 100, wherein the organic planarization layer 150 is laid down thick enough to cover both the first and the second sidewalls 105a,105b, and wherein the first height 110a is greater than the second height 110b; removing a part of the organic planarization layer 150, wherein a first depth 155 of the first sidewalls 105a is exposed; removing the exposed first depth 155 of the first sidewalls 105; and removing the remaining organic planarization layer 150.

The embodiments of the present disclosure described above are intended to be merely exemplary. It will be appreciated by those of skill in the art that alterations, modifications and variations to the illustrative embodiments disclosed herein may be made without departing from the scope of the present disclosure. Moreover, selected features from one or more of the above-described exemplary embodiments may be combined to create alternative embodiments not explicitly shown and described herein.

The present disclosure may be embodied in other specific forms without departing from its spirit or essential characteristics. The described exemplary embodiments are to be considered in all respects only as illustrative and not restrictive. The scope of the disclosure is, therefore, indicated by the appended claims rather than by the foregoing description. All changes that come within the meaning and range of equivalency of the claims are to be embraced within their scope.

What is claimed is:

1. A method for reducing sidewall height nonuniformity in sidewall image transfer processes, comprising:
depositing an organic planarization layer over an integrated circuit structure after sidewall definition, mandrel removal, and etch of exposed portions of a first underlying layer in a sidewall image transfer process,
wherein the organic planarization layer is laid down thick enough to cover both one or more first and one or more second sidewalls,
wherein the one or more first sidewalls have a first height and the one or more second sidewalls have a second height, and
wherein the first height is greater than the second height;
removing a part of the organic planarization layer,
wherein a first depth of the one or more first sidewalls is exposed and
wherein the organic planarization layer covers the one or more second sidewalls by a second depth;
removing the exposed first depth of the one or more first sidewalls; and
removing the remaining organic planarization layer.

2. The method as recited in claim 1, wherein the organic planarization layer comprises a hydrocarbon component of greater than approximately 75% and less than approximately 90% by weight with the remaining components comprising a combination of oxygen with hydrogen, and nitrogen of greater than approximately 5% and less than approximately 20% by weight.

3. The method as recited in claim 1, wherein the second depth is greater than or equal to zero.

4. The method as recited in claim 1, wherein the part of the organic planarization layer is removed by reactive ion plasma etching.

5. The method as recited in claim 1, wherein the exposed first depth of the one or more first sidewalls is removed by reactive ion plasma etching.

6. A method for reducing sidewall height nonuniformity in sidewall image transfer processes, comprising:
depositing an organic planarization layer over an integrated circuit structure after sidewall definition, mandrel removal, and etch of exposed portions of a first underlying layer in a sidewall image transfer process,
wherein the organic planarization layer is laid down thick enough to cover both one or more first and one or more second sidewalls,
wherein the one or more first sidewalls have a first height and the one or more second sidewalls have a second height, and
wherein the first height is greater than the second height;
removing a part of the organic planarization layer,
wherein a first depth of the one or more first sidewalls is exposed and
wherein a second depth of the one or more second sidewalls is exposed;
removing the exposed first depth of the one or more first sidewalls and the exposed second depth of the one or more second sidewalls; and
removing the remaining organic planarization layer.

7. The method as recited in claim 6, wherein the organic planarization layer comprises a hydrocarbon component of greater than approximately 75% and less than approximately 90% by weight with the remaining components comprising a combination of oxygen with hydrogen, and nitrogen of greater than approximately 5% and less than approximately 20% by weight.

8. The method as recited in claim 6, wherein the second depth is greater than or equal to zero.

9. The method as recited in claim 6, wherein the part of the organic planarization layer is removed by reactive ion plasma etching.

10. The method as recited in claim 6, wherein the exposed first depth of the first sidewalls and the exposed second depth of the second sidewalls are removed by reactive ion plasma etching.

11. An integrated circuit structure having reduced sidewall height nonuniformity in sidewall image transfer processes, comprising:
one or more first sidewalls having a first height; and
one or more second sidewalls having a second height,
wherein after sidewall definition, mandrel removal, and etch of exposed portions of a first underlying layer the difference between the first height and the second height is reduced by
depositing an organic planarization layer over the integrated circuit structure,
wherein the organic planarization layer is laid down thick enough to cover both the first and the second sidewalls, and
wherein the first height is greater than the second height;
removing a part of the organic planarization layer,
wherein a first depth of the first sidewalls is exposed;
removing the exposed first depth of the first sidewalls; and
removing the remaining organic planarization layer.

12. The integrated circuit structure as recited in claim 11, wherein the organic planarization layer comprises a hydrocarbon component of greater than approximately 75% and less than approximately 90% by weight with the remaining components comprising a combination of oxygen with hydrogen, and nitrogen of greater than approximately 5% and less than approximately 20% by weight.

13. The integrated circuit structure as recited in claim 11,
wherein the removal of a part of the organic planarization layer further comprises exposing a second depth of the second sidewalls, and
wherein the removal of the exposed first depth of the first sidewalls further comprises removing the exposed second depth of the second sidewalls.

14. The integrated circuit structure as recited in claim 13, wherein the second depth is greater than or equal to zero.

15. The integrated circuit structure as recited in claim 13, wherein the exposed first depth of the first sidewalls and the exposed second depth of the second sidewalls are removed by reactive ion plasma etching.

16. The integrated circuit structure as recited in claim 11, wherein the part of the organic planarization layer is removed by reactive ion plasma etching.

17. The integrated circuit structure as recited in claim 11, wherein the exposed first depth of the first sidewalls is removed by reactive ion plasma etching.
